(19) United States
(12) Patent Application Publication
(10) Pub. No.: US 2024/0329004 A1
(43) Pub. Date: Oct. 3, 2024

(54) MULTI-HOLDER INSPECTION SYSTEM USING MOVEABLE SUPPORT STRUCTURE

(71) Applicant: Sonix, Inc., Springfield, VA (US)

(72) Inventors: Young-Shin Kwon, Chantilly, VA (US); Thaladi Kumar Masilamani, Burke, VA (US); Bovly Yassa, Manassas, VA (US); Paul Ivan John Keeton, Woodbridge, VA (US)

(73) Assignee: Sonix, Inc., Springfield, VA (US)

(21) Appl. No.: 18/624,537

(22) Filed: Apr. 2, 2024

Related U.S. Application Data
(60) Provisional application No. 63/456,706, filed on Apr. 3, 2023.

(51) Int. Cl. G01N 29/22; G01N 29/27; G01N 29/28; H01L 21/66

(52) U.S. Cl. CPC G01N 29/225; G01N 29/27; G01N 29/28; H01L 22/12

(57) ABSTRACT

An ultrasonic inspection system includes an ultrasonic scanning station, a support structure and two or more object holders coupled to the support structure. The support structure is moveable between first and second orientations. The object holders enable an object to be held for ultrasonic scanning. In the first orientation of the support structure, a first object holder is to be held in an ultrasonic scanning station and a second object holder is positioned to allow loading or unloading. In the second orientation, the second object holder is positioned in the ultrasonic scanning station and the first object holder is positioned to allow loading or unloading. The object holders may be raised above a water level for loading/unloading and lowered below the water level for ultrasonic inspection. The object holders may have wafer raisers to hold a semiconductor wafer above the object holder for automated handling.

### RELATED APPLICATIONS

This application claims the benefit of provisional application Ser. No. 63/456,706 filed Apr. 3, 2023 and titled “Multi-chuck Inspection System,” the entire contents of which are hereby incorporated by reference.

### BACKGROUND

Ultrasonic inspection equipment is used to perform Non-Destructive Test (NDT) on semiconductor wafers or packages to detect potential quality issues or manufacturing defects. Semiconductor manufacturers are constantly looking to reduce inspection time in order to increase productivity in the production phase. Therefore, inspection time needs to be reduced to improve productivity.

Currently available ultrasonic inspection equipment have one or more stationary wafer chucks with one long scanning axis motor assembly or dual independent assemblies to perform the scan. Each wafer chuck may offer one or more ultrasonic transducers to reduce overall scan time. These systems offer increased throughput by scanning multiple wafers in parallel. However, throughput is still limited by the changeover time between scans. Currently available equipment has a significant delay while previous wafers are removed from the wafer chucks and new wafers are placed on the wafer chucks before the next scans can begin.

### BRIEF DESCRIPTION OF THE DRAWINGS

The accompanying drawings provide visual representations which will be used to describe various representative embodiments more fully and can be used by those skilled in the art to understand better the representative embodiments disclosed and their inherent advantages. In these drawings, like reference numerals identify corresponding or analogous elements.

FIG. 1 shows an ultrasonic inspection system, in accordance with various representative embodiments.

FIG. 2 and FIG. 3 illustrate an example scanner of an inspection system, in accordance with various representative embodiments.

FIG. 4 shows a scanner of an ultrasonic inspection system, in accordance with various representative embodiments.

FIG. 5 shows a wafer chuck assembly with height adjustable wafer chucks, in accordance with various representative embodiments.

FIG. 6 and FIG. 7 show a scanner of an inspection system, in accordance with various representative embodiments.

FIG. 8 shows a wafer chuck assembly with height adjustable wafer chucks, in accordance with various representative embodiments.

FIG. 9 is a flow chart of method of ultrasonic inspection, in accordance with various representative embodiments.

FIG. 10 shows a wafer without die attached.

FIG. 11 shows a wafer with die attached.

FIG. 12A and FIG. 12B show wafer chucks with wafer riser mechanisms, in accordance with various representative embodiments.

FIG. 13 shows a side view of wafer chuck with wafer riser mechanisms, in accordance with various representative embodiments.

FIG. 14A and FIG. 14B are further views of wafer chucks with wafer riser mechanisms, in accordance with various representative embodiments.

FIG. 15 shows a side view of wafer chuck with wafer riser mechanisms, in accordance with various representative embodiments.

FIG. 16 illustrates a working principle for handling wafers, in accordance with various representative embodiments.

FIG. 17 is a flow chart of a method of operation of a wafer chuck with wafer risers, in accordance with various representative embodiments.

### DETAILED DESCRIPTION

The various apparatus and devices described herein relate to test and measurement systems, and more particularly to inspection systems, such as a system for ultrasonic inspection of a device under test (DUT), and inspection methods.

While this present disclosure is susceptible of embodiment in many different forms, there is shown in the drawings and will herein be described in detail specific embodiments, with the understanding that the embodiments shown and described herein should be considered as providing examples of the principles of the present disclosure and are not intended to limit the present disclosure to the specific embodiments shown and described. In the description below, like reference numerals are used to describe the same, similar or corresponding parts in the several views of the drawings. For simplicity and clarity of illustration, reference numerals may be repeated among the figures to indicate corresponding or analogous elements.

Current systems for ultrasonic inspection of semiconductor wafers have a significant delay while previous wafers are removed from the wafer chucks that hold the wafers for inspection and new wafers are placed on the wafer chucks before the next scans can begin. The various systems disclosed herein increase throughput minimizing changeover time between scans in addition to minimizing scan time.

Embodiments of the disclosure include a multi-chuck platform that can handle more than two wafer chucks and an integrated support structure (such as an index table or carousel) for seamless wafer/package handling and scanning. This significantly increases throughput by loading, aligning and queuing up the next wafer or package while the previous inspection is in progress.

Various embodiments provide an ultrasonic inspection system that includes one or more ultrasonic scanning stations, one or more support structures and a number of object holders coupled to the support structures. A support structure may be moveable, such as a rotatable index table, for example. Each object holder is configured to hold an object for ultrasonic scanning. Each support structure is moveable, and may be rotatable, between a first orientation and a second orientation. In the first orientation of the support structure, a first object holder is positioned to allow loading or unloading of the first object holder and a second object holder is positioned in an ultrasonic scanning station of the one or more ultrasonic scanning stations. In the second orientation of the support structure, the second object holder is positioned to allow loading or unloading of the second object holder and the first object holder is positioned in the ultrasonic scanning station. An object holder may be a wafer chuck configured to hold a semiconductor wafer for ultrasonic scanning.

An ultrasonic scanning station includes an ultrasonic transducer. In one embodiment, ultrasound from the transducer is coupled to an object using a water coupler. In another embodiment, the ultrasonic inspection system includes a scan tank for containing water. In this embodiment, ultrasound is coupled to the object by immersing the transducer and the object in the tank of water. In some embodiments, the scanning station can use other scanning devices and/or other scanning techniques.

In some embodiments, an object may be held in the scan tank for ultrasonic inspection. An object holder may be coupled to a support structure by a mechanism for moving a held object between a first position above water in the scan tank (for loading and unloading) and a second position submerged in the water in the scan tank (for ultrasonic scanning). An object holder is coupled to a support structure by three actuators configured to adjust an orientation of the object holder in an ultrasonic scanning station.

A wafer chuck of the ultrasonic inspection system may include wafer risers located in a peripheral region of the wafer chuck. The wafer risers may be lifted to support a semiconductor wafer in a first position above the wafer chuck to enable a robotic positioning arm to pass between the wafer chuck and an underside of the semiconductor wafer. The wafer risers may be lowered to a second position, below the first position, to enable the semiconductor wafer to be supported, at its underside, by the wafer chuck.

Various embodiments provide a method of operation of an ultrasonic inspection system including moving, i.e. rotating, a support structure to a first orientation for which a first object holder coupled to the support structure is located outside of an ultrasonic scanning station of the ultrasonic inspection system and a second object holder coupled to the support structure is located in the ultrasonic scanning station, performing an ultrasonic scan of an object in the second object holder, unloading an object previously scanned from the first object holder, loading an object of the plurality of objects to be scanned into the first object holder, moving, i.e. rotating, the support structure to a second orientation for which the first object holder is located in the ultrasonic scanning station and the second object holder is located outside of the ultrasonic scanning station, performing an ultrasonic scan of the object in the first object holder, unloading an object previously scanned from the second object holder, and loading an object to be scanned into the second object holder.

An embodiment may include raising the first object holder out of a water tank for unloading an object previously scanned from the first object holder, lowering the first object holder into the water tank for scanning an object in the first object holder, raising the second object holder out of a water tank for unloading an object previously scanned from the second object holder, and lowering the second object holder into the water tank for scanning an object in the second object holder. In one embodiment, the object holders are raised and lowered when positioned for loading and unloading. However, in general, the object holders could be raised or lowered at any orientation of the support structure.

An embodiment may include raising wafer risers located in a peripheral region of the wafer chuck, placing a semiconductor wafer on the plurality of risers using a robotic positioning arm positioned between a lower surface of the semiconductor wafer and an upper surface of the wafer chuck, withdrawing the robotic positioning arm, and lowering the wafer risers to place the underside of semiconductor wafer on the upper surface of the wafer chuck.

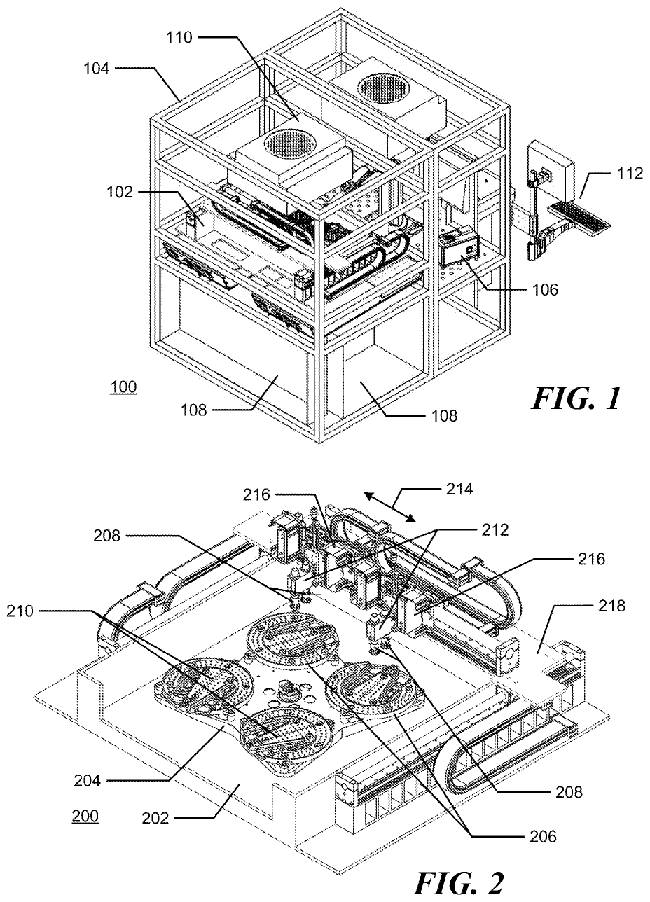

FIG. 1 shows an ultrasonic inspection system 100, in accordance with various representative embodiments. Scanner 102, located in enclosure 104, is the core process module of the system and performs the wafer/package inspection. Enclosure 104 also contains robot module 106 for wafer handling, electrical, plumbing and computer control panels 108, and air filters 110. A user interface 112 is also provided. Between scans, a previous wafer is removed from a chuck and the next wafer loaded. An embodiment of the present disclosure minimizes the wait time between scans by integrating a rotatable chuck support structure, such as an index table or carousel, in the scan tank of scanner.

The disclosure is described below with reference to a semiconductor wafer chuck. A wafer chuck is typically used to support a semiconductor wafer during the inspection process. A wafer may be held on the wafer chuck by drawing a vacuum between the wafer and a surface of the wafer chuck. However, it is to be recognized that, in some implementations, other types of object holders may be used instead of the wafer chuck. The object holder may be any holding mechanism to support a wafer, tray, package or other object or device under test. The methods are not exclusive to semiconductor wafers and packages and can be used for any sample type.

Further, the disclosure is described below with reference to a moving or rotating index table or carousel. However, various support structures may be used in place of the rotating index table. For example, each object holder may be supported by a rotatable arm, with two of more arms coupled to a central pivot to form a support structure.

Ultrasonic Inspection Equipment with Quad Wafer Chucks in Single Carousel.

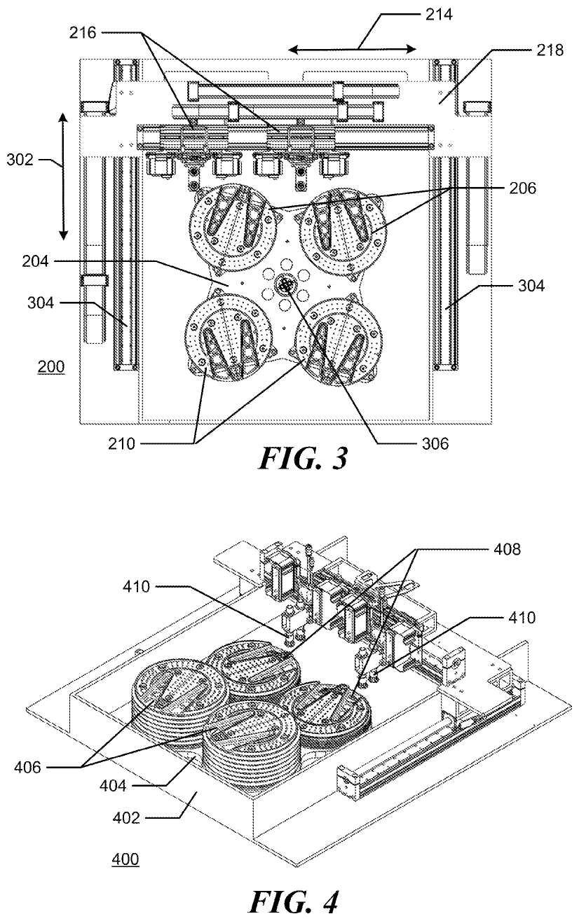

FIG. 2 and FIG. 3 illustrate an example scanner 200 of an inspection system, in accordance with various representative embodiments. In the example embodiment shown in FIG. 2, scanner 200 is built around a scan tank 202. Support structure 204 is a moveable, rotating index table (carousel) located inside the scan tank. The support structure 204 is configured for four wafer chuck and their corresponding wafers. Two wafer chucks 206 are positioned for scanning beneath ultrasound transducers 208 of ultrasonic scanning stations, while two wafer chucks 210 are positioned to allow loading and unloading of wafers. A scanning station is the region of scanner 200 where an object is held for inspection. Two scanning stations are shown in FIG. 2, each scanning station includes an ultrasound transducer 208, a transducer mount 212 that holds the ultrasound transducers and a forcer assembly 216. Forcer assemblies 216 are mounted on scan bridge 218 and move the ultrasound transducers in scan axis direction 214 to scan wafers in the ultrasonic scanning station. Forcer assemblies 216 may be capable of independent movement with respect to each other. A scanning station may also include a water coupler to supply water that acoustically couples ultrasound generated by a transducer to the object under test.

FIG. 3 is view of scanner 200 from above, in accordance with various representative embodiments. A raster scan of wafers in wafer chucks 206 may be obtained by moving transducer 208 in scan axis direction 214 and moving scan bridge 218 in step axis direction 302 along step axis side rails 304. Wafer chucks 210 are available for loading and unloading wafers. Support structure 204 is rotatable through 180° using motorized swivel spindle 306. A sample wafer or package may be placed on wafer chucks 210 automatically, using an atmospheric robot, or manually by an operator. Once the wafers or packages have been loaded on to wafer chucks 210 the system rotates support structure 204 through 180° to position the samples in the ultrasonic scanning stations ready for inspection. The scanning process is then started to inspect the samples on wafer chucks 210. Simultaneously, wafer chucks 206, which are now rotated out of the scanning stations, are loaded with new samples. Once the inspection of samples on wafer chucks 210 is completed, support structure 204 rotates through 180° back to its original position, to enable the samples to be unloaded. While the inspected samples on wafer chucks 210 are being unloaded, and new samples are being loaded into wafer chucks 210, the scanner can simultaneously start inspecting the samples on wafer chucks 206. This process minimizes the downtime between scans by preparing the next samples in parallel with the inspection process. In turn, this maximizes system throughput. While a rotation of 180° is described herein, other degrees of rotation could be used.

The example embodiment shown in FIG. 2 and FIG. 3, the support structure is a swivel index table or carousel that supports four wafer/package chucks. However, several variations and modifications can be made. For example, an ultrasonic scanner may have two, three, four or more wafer chucks. While the example scan axis forcer assembly has two forcers, a single forcer could be used or multiple forcers. In addition, a transducer mount could be capable to hold one, two or multiple transducers to minimize scan time. In some embodiments, the support structure can accommodate any number of wafer/package chucks, and similarly, any number of forcers and transducer mounts can be used for any number of wafer/package chucks.

### Height Adjustable Quad Wafer Chucks in Single Carousel

FIG. 4 shows a scanner of an ultrasonic inspection system, in accordance with various representative embodiments. In the example embodiment shown in FIG. 4 scanner 400 is built around scan tank 402 and a rotating support structure 404 is located inside the scan tank. In this example embodiment, support structure 404 is an index table or carousel. Wafer chucks 406 are positioned for loading and unloading wafers, while wafer chucks 408 are positioned in scanning stations ready for inspection using transducers 410. In operation, sample wafers or packages are placed on wafer chucks 406 automatically by a robot handler or manually by an operator. Once the wafers or packages have been loaded on to wafer chucks 406, the system rotates support structure 404 through 180° to position the samples in the scanning stations ready for inspection. The scanning process is started to inspect the samples on wafer chucks 406. Simultaneously wafer chucks 408 are being loaded with new samples. Once the inspection of samples on wafer chucks 406 is completed, the carousel support structure rotates back to its original position to enable the samples to be unloaded. While the inspected samples on wafer chucks 406 are being unloaded, and new samples are being loaded, the scanner can simultaneously start inspecting the samples on wafer chucks 408. Minimizing downtime between scans, by preparing the next samples in parallel with the inspection process, maximizes system throughput. While a rotation of 180° is described herein, other degrees of rotation could be used.

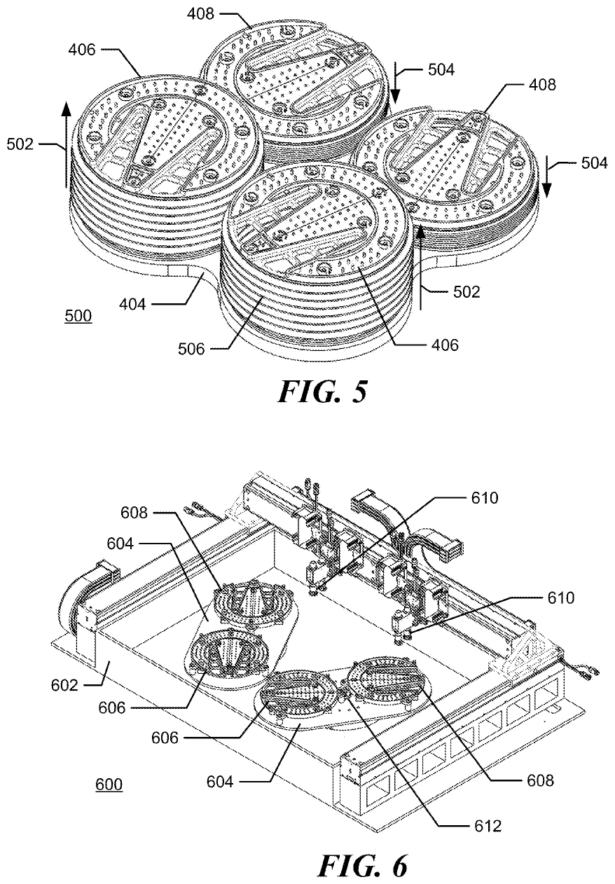

FIG. 5 shows a wafer chuck assembly 500 with height adjustable wafer chucks, in accordance with various representative embodiments. In the implementation shown, wafer chuck assembly 500 includes four wafer chucks coupled to swivel index table support structure 404. Each wafer chuck is configured to be raised up and lowered down using one or more holder risers. A holder riser may be an electro-mechanical or pneumatic actuator, for example, that couples between the holder and the support structure. Wafer chucks 406 are depicted in a raised position, as indicated by arrows 502, while wafer chucks 408 are depicted in a lowered position, as indicated by arrows 504. This height adjustment enables the inspection system to perform the ultrasonic scanning under water, with the wafer chucks 408 and their corresponding wafers submerged in a scan tank. Prior to scanning, the mounting surfaces of the wafer chucks outside of the scanning stations are raised above the water level, enabling a robot or technician to place the sample wafers or packages in the wafer chucks. The wafer chucks are then submerged beneath the water and support structure 404 is rotated to allow scanning of the sample wafers or packages.

In accordance with an embodiment, a height adjustable wafer chuck may utilize two or more holder risers. The holder risers may be actuated independently to adjust the tilt of a wafer about one or two axes. The tilt may be adjusted to align a wafer parallel with a scanning plane, for example.

Optionally, flexible bellows 506 may be used to enclose and protect a height adjustment mechanism for the wafer chuck. Height adjustment may be achieved by electro-mechanical, mechanical or pneumatic means, for example, or a combination thereof.

In the example embodiment shown in FIG. 4 and FIG. 5, the support structure 404 is a swivel index table that supports four wafer/package chucks. However, as described above, several variations and modifications can be made. For example, an ultrasonic scanner may have two, three, four or more wafer chucks. While the example scan axis forcer assembly has two forcers, a single forcer or more than two forcers may be used in other embodiments. In addition, the transducer mounts could be capable of holding one, two or multiple transducers. In some embodiments, the support structure can accommodate any number of wafer/package chucks, and similarly, any number of forcers and transducer mounts can be used for any number of wafer/package chucks.

Height adjustable wafer chucks enable the ultrasonic inspection system to perform the ultrasonic scanning of wafers under water by raising the wafer chucks up and lowering them down. This eliminates the need for water couplers in the scanning process since the whole scanning process can be performed underwater. In turn, less water tubing is needed and less water is needed for scanning.

### Quad Wafer Chucks in Dual Carousel

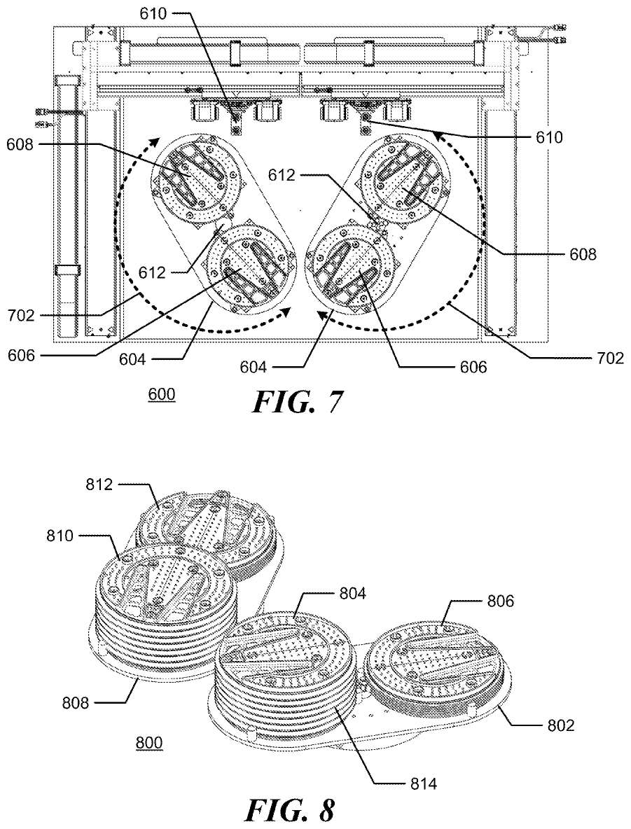

FIG. 6 and FIG. 7 show a scanner 600 of an inspection system, in accordance with various representative embodiments. Referring to FIG. 6, the scanner is built around scan tank 602. Two rotating support structures 604 are located adjacent to one another inside the scan tank. With the support structures 604 oriented as shown, wafer chucks 606 are positioned for loading and unloading while wafer chucks 608 are positioned in the scanning stations for scanning by transducers 610. Rotating support structures 604 are configured to rotate about swivel spindles 612.

FIG. 7 is a view, from above, of scanner 600, in accordance with various representative embodiments. Sample wafers or package are automatically placed on wafer chucks 606 using an atmospheric robot or manually placed by an operator. Once the wafers or packages have been loaded on to wafer chucks 606, the system rotates both support structures 604 through 180°, as indicated by arrows 702, to position the samples ready for inspection using motorized swivel spindles 612 or an equivalent mechanism. The scanning process is then started to inspect the samples on wafer chucks 606. Simultaneously wafer chucks 608 are being loaded with new samples. Once the inspection of samples on wafer chucks 606 is completed, both support structures 604 are rotated through 180° back to their original positions to unload the samples. While the inspected samples on wafer chucks 606 are being unloaded and new samples are being loaded into wafer chucks 606, the scanner can simultaneously start inspecting the samples on wafer chucks 608. This minimizes downtime between scans, by preparing the next samples in parallel with the inspection process, and maximizes system throughput. While a rotation of 180° is described herein, corresponding to object holders placed diametrically opposite one another on a rotating support, other degrees of rotation could be used. For example, the angle between object holders may be less than or greater than 180°.

The example embodiment shown in FIG. 6 and FIG. 7 has dual rotatable support structures that together support four wafer/package chucks. However, several variations and modifications can be made. For example, the scanner may use fewer or more wafer chucks and the scan axis forcer assembly may have two forcers, a single forcer or multiple forcers. In addition, the transducer mounts could each be capable of holding one, two or multiple transducers. Using fewer wafer chucks on a support structure allows better stability and alignment of the wafer chucks since the individual swivel mechanisms enable the wafer chucks to be controlled very precisely. In addition, the manufacturing cost may be reduced. In some embodiments, the support structures can accommodate any number of wafer/package chucks, and similarly, any number of forcers and transducer mounts can be used for any number of wafer/package chucks.

### Height Adjustable Quad Wafer Chucks in Dual Carousel

FIG. 8 shows a wafer chuck assembly 800 with height adjustable wafer chucks, in accordance with various representative embodiments. Wafer chuck assembly 800 includes first rotatable support structure 802, supporting height adjustable wafer chucks 804 and 806, and second rotatable support structure 808 supporting height adjustable wafer chucks 810 and 812. As discussed above with reference to FIG. 5, the upper mounting surface of the wafer chucks may be raised above water in a scan tank to enable loading and unloading of wafers or packages and may be lowered below the surface of the water in the scan tank for ultrasonic inspection. The sample wafers or packages are automatically placed on wafer chucks 804 and 810 using an atmospheric robot or manually placed by an operator. Once the wafers or packages have been loaded on to wafer chucks 804 and 810, the system rotates both support structures through 180° to position the samples ready for inspection. The scanning process is started to inspect the samples on wafer chucks 804 and 810. Simultaneously wafer chucks 806 and 812 are loaded with new samples. Once the inspection of samples on wafer chucks 804 and 810 is completed, both support structures are rotated through 180° back to their original positions to enable the samples to be unloaded. While the inspected samples on wafer chucks 804 and 810 are being unloaded, and new samples are being loaded into wafer chucks 804 and 810, the scanner can simultaneously start inspecting the samples on wafer chucks 806 and 812. This minimizes downtime between scans by preparing the next samples in parallel with the inspection process and maximizes system throughput. Flexible bellows 814 may be used to cover and protect a riser mechanism of the object holder.

In the embodiments shown in FIGS. 6-8, the two support structures are configured to reduce the required size of the scan tank. In particular, the motorized swivel spindles are positioned such that wafer chucks 806 and 812 in the scanning stations are located further apart than wafer chucks 804 and 810 positioned for loading and unloading. Parallel support structures would require the pivot points to be farther apart to maintain the same transducer separation, requiring a wider tank. In this configuration, there is insufficient space to rotate the two support structures together. Moving, such as by rotation of support structures 802 and 808, may be performed sequentially to provide sufficient clearance between the support structures. For example, rotation of one support structure may begin before rotation of the other support structure to provide sufficient clearance between the first and second support structures during rotation.

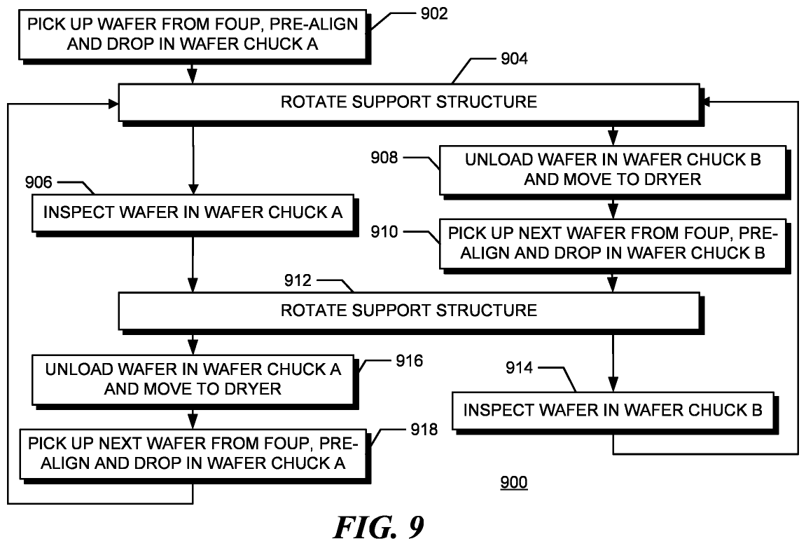

FIG. 9 is a flow chart of method 900 of ultrasonic inspection, in accordance with various representative embodiments. FIG. 9 depicts operation of each of one or more support structures, each support structure supporting two or more wafer chucks. As discussed above, a support structure may support more than two wafer chucks, and one or more support structures may be used in a scanner. When two or more support structures are used, they may operate synchronously or sequentially with one another each in accordance with flow 900. Referring to FIG. 9, at block 902 a wafer to be inspected is picked up from a carrier such as a Front Opening Unified Pod (FOUP), pre-aligned with wafer chuck A of a scanner and dropped onto wafer chuck A. At block 904, a support structure supporting wafer chuck A and wafer chuck B is rotated to position wafer chuck A in a scanning station of the scanner and to position wafer chuck B for loading and unloading. At block 906, the wafer in wafer chuck A is inspected. While wafer A is being inspected, another wafer (if any) is unloaded from wafer chuck B and moved to a dryer at block 908. A next wafer is picked up from the FOUP, pre-aligned and placed on wafer chuck B at block 910. At block 912, the support structure is rotated again to position wafer chuck B in a scanning station of the scanner and position wafer chuck A for loading and unloading. At block 914, the wafer in wafer chuck B is inspected. While the wafer is being inspected, the wafer is unloaded from wafer chuck A and moved to a dryer at block 916. A next wafer is picked up from the FOUP, pre-aligned and placed on wafer chuck A at block 918. Flow returns to block 904 and the repeats until there are no more wafers to scan, and the scanned wafers have been unloaded.

Block 906 is performed in parallel with blocks 908 and 910. Blocks 916 and 918 are performed in parallel with block 914.

In some embodiments, method 900 may be used with multiple support structures simultaneously. In such embodiments, each block of method 900 may occur with one support structure simultaneously as a corresponding block with another support structure. For example, at block 906, a first wafer in wafer chuck A of a first support structure is inspected, and simultaneously, a second wafer in wafer chuck A of a second support structure is inspected. Similarly, at blocks 908, a third wafer is unloaded in wafer chuck B of the first support structure and moved to a dryer, while a fourth wafer is unloaded in wafer chuck B of the second support structure. Accordingly, each block of method 900 may occur with more than one support structure. Furthermore, the support structures are configured to ensure rotation such that each of the support structures do not hinder each other.

When the wafers are loaded and unloaded automatically by a robotic handler, the same handler may be used to retrieve wafers from the dryer and return them to the FOUP or pass them to another process.

### Wafer Handling

As discussed above, an object holder may be a wafer chuck, for example. A wafer chuck is a mechanical or electro-mechanical or pneumatic mechanism, or combination thereof, for holding a semiconductor wafer in place firmly while the wafer is being processed. The wafer chuck is an important part of any semiconductor machinery as it handles the wafers directly for various processes.

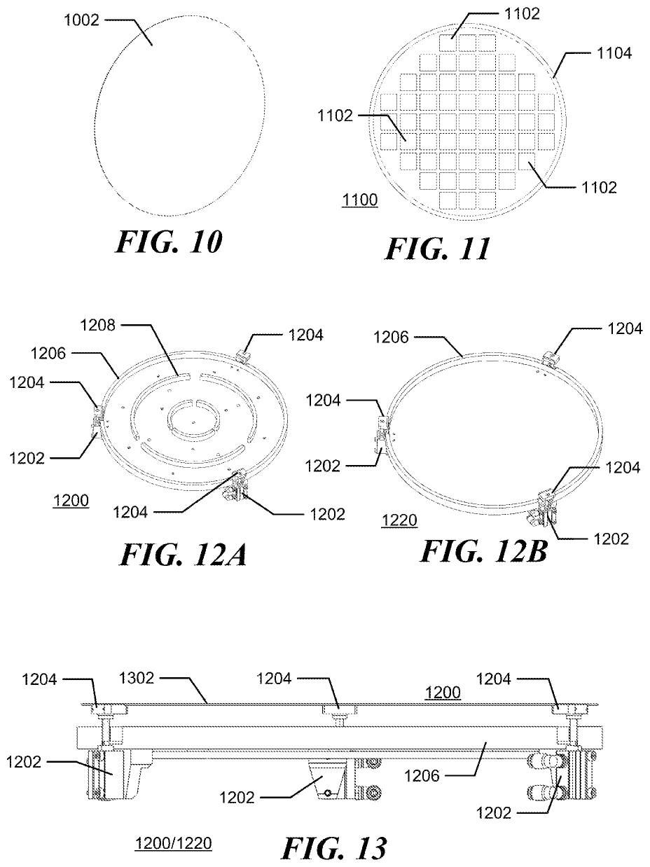

In general, wafers can be categorized as “Wafer without die” and “Wafer with die.” FIG. 10 depicts a first category where wafer 1002 does not contain any die on the wafer surface, usually these kinds of wafers are smooth on both sides. FIG. 11 depicts a second category in which wafer 1104 has semiconductor die 1102 attached to the wafer surface. Usually, these wafers have multiple dies attached to one side of the surface which make the wafer surface uneven depending on the thickness of the dies.

Both categories of wafers may be used in the same system for processing, scanning or inspecting wafers during manufacture. Often, different kinds of wafers (“Wafer without die” and “Wafer with die”) use different wafer chucks to hold them. In this case, the wafer chuck must be swapped manually every time the semiconductor machinery switches from one kind of wafer to another. These manual wafer chuck swaps result in more downtime and less productivity. Any reduction in system downtime can result in improved productivity.

Wafers with Die need to be picked up by using the surface of the wafer on which no dies are present in order to prevent damage to the dies. This may be the top or bottom surface depending upon the application. Wafers without Die are typically picked up using the wafer's bottom surface, but in some applications may be handled by the top surface. Hence, it is advantageous for a wafer chuck to work with different types of wafer handlers.

Embodiments of the present disclosure provide a wafer chuck configured to hold both kinds of wafers (“Wafer without die” and “Wafer with die”) in a single wafer chuck design. This can significantly increase throughput by avoiding wafer chuck swaps when the type of wafer is changed. The wafer is held only at the wafer edge and a riser mechanism is used to lift the wafer above the wafer chuck whenever necessary to pick up and load the wafer from the wafer chuck.

FIG. 10 shows a wafer 1002 prior to fabrication of semiconductor die. A wafer without die 1002 is typically picked-up using the bottom surface of the wafer.

FIG. 11 shows a wafer 1100 with fabricated die 1102. Wafer 1100 may be touched and picked up using the non-die surface (the top surface in the figure) of the wafer. Wafer 1100 also has a die “keep out” zone 1104 from the edge at the bottom of the wafer. It is allowable to touch and hold only the wafer's bottom surface in the keep out zone, if required.

FIG. 12A shows a wafer chuck 1200 with wafer riser mechanisms 1202, in accordance with various representative embodiments. The wafer riser mechanisms have pins 1204 for raising and lowering a wafer. Pins 1204 may be raised above external ring 1206 of the wafer chuck body, as shown in the figure. The wafer riser mechanism can be actuated through mechanical, pneumatic, electro-mechanical means, for example. Wafer chuck 1200 includes inner rings 1208 that support the inner region of a wafer.

FIG. 12B shows a further wafer chuck 1220 with wafer riser mechanisms 1202, in accordance with various representative embodiments. Wafer chuck 1220 has an external ring 1206, which supports the outer rim of a wafer, but has no inner rings to ensure no contact with the die on the wafer.

To enable handling of wafer from below, the rings of prior wafer handlers are indented to allow the handler to be removed after the wafer has been placed on the wafer chuck. The use of wafer risers, as disclosed herein, allows a complete outer ring to be used without indentations to accommodate the handler. In one embodiment, a wafer chuck has a complete outer ring configured to support an outer region of the underside of a wafer. Having a complete outer ring allows more control over the inspection process to optionally immerse the surface of the wafer or optionally protect the edge of the wafer to minimize water ingress. This will depend on the application. This control is not possible with an indented wafer handler and thus is an advantage of the wafer riser.

FIG. 13 shows a side view of wafer chuck 1200 or wafer chuck 1220, in accordance with various representative embodiments. In this view, the three pins 1204 of the wafer riser mechanism are raised to support wafer 1302.

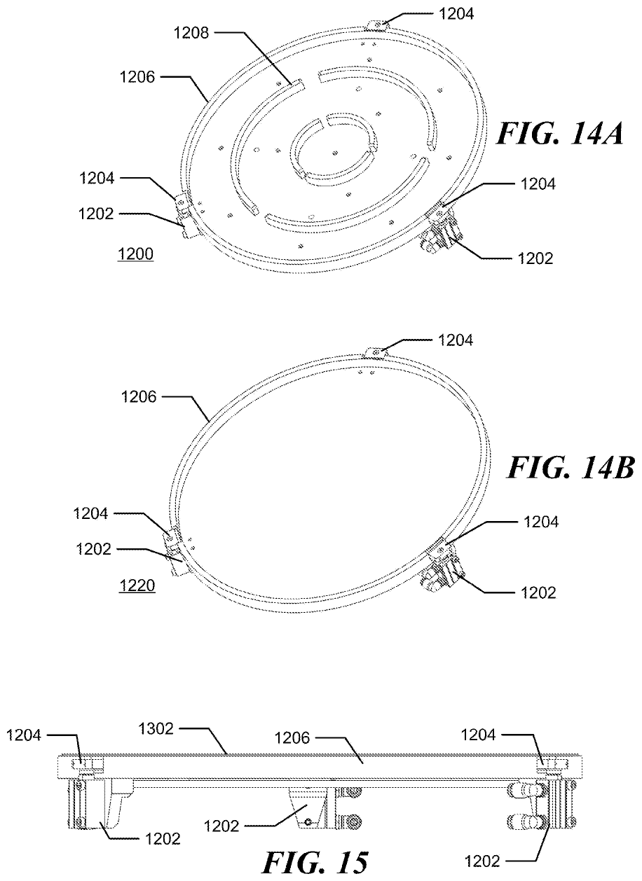

FIG. 14A is a further view of wafer chuck 1200 with wafer riser mechanisms 1202, in accordance with various representative embodiments. In this view, pins 1204 are lowered to a position at or below the upper surface of external ring 1206. Wafer chuck 1200 includes inner rings 1208 that support the inner region of a wafer.

FIG. 14B shows a corresponding view of wafer chuck 1220 without any inner rings.

FIG. 15 shows a side view of wafer chuck 1200 or 1220, in accordance with various representative embodiments. In this view, the three pins 1204 are lowered, causing wafer 1302 to be supported by the upper surface of external ring 1206.

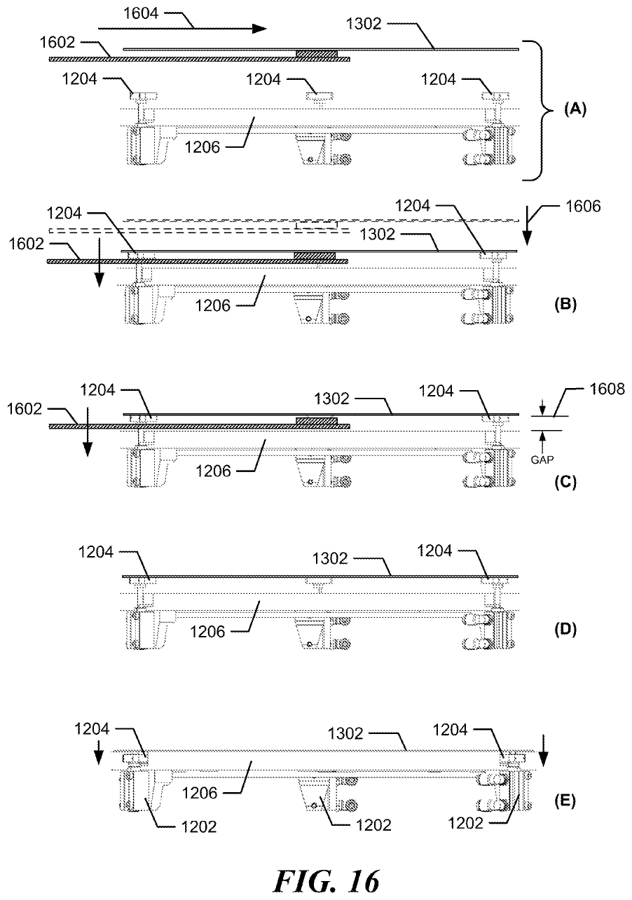

FIG. 16 illustrates a working principle for handling “Wafers without Die,” in accordance with various representative embodiments. The same working principle may be used for applications where the die are fabricated on the top side of the wafer. In some implementations, an end effector 1602 at the end of a robot arm is used to hold and transport wafer 1302 from one station to another. End effector 1602 is a gripping tool for automatic handling of the wafers. As depicted in configuration (A) in FIG. 16, for Wafers without Die, end effector 1602 holds wafer 1302 using the wafer's bottom surface and pre-aligns the wafer with the external ring 1206 of the wafer chuck, as indicated by arrow 1604. In configuration (B), the end effector is lowered, as indicated by arrow 1606. This places wafer 1302 on pins 1204 of the wafer riser mechanism. In configuration (C), end effector 1602 is lowered farther. At this position, the end effector is in between wafer 1302 and the upper surface of the wafer chuck. Thus, the wafer riser mechanism is capable of creating a space 1608 between the wafer and the wafer chuck sufficient to allow the end effector to pass between the wafer and the wafer chuck and be withdrawn, as depicted in configuration (D). Once the wafer is placed on the wafer riser mechanism, the mechanism is lowered to place the wafer on the wafer chuck's external ring, as depicted in configuration (E). The wafer is then rigidly attached to the wafer chuck using vacuum or any other similar means.

Working Principle to Handle “Wafers with Die”

Wafers with Die on the top side of the wafer may be handled as described above in reference to FIG. 16. Alternatively, when the die are on the bottom side of the wafer, an end effector holds the wafer using the wafer's top surface (using vacuum or edge grip) and places the wafer at the wafer chuck's external ring with the wafer risers in the lowered position. Note that wafer's bottom surface has die and it is not allowed to touch the die surface while handling the wafers. At this point, the end effector will be above the wafer top surface. Once the wafer is placed onto the wafer chuck's external ring, the wafer is rigidly attached to the wafer chuck using vacuum or any other similar means. Here, only the wafer's keep out zone is in contact with the wafer chuck external ring.

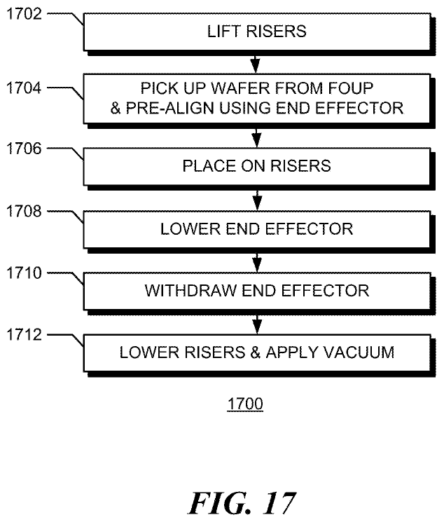

FIG. 17 is a flow chart of a method 1700 of operation of a wafer chuck with wafer risers, in accordance with various representative embodiments. The method may be used for wafers without die or for wafers with die on the top surface of the wafer. At block 1702, the wafer risers are lifted. At block 1704, a wafer without die is picked up from a FOUP or other holder using a robot end effector and pre-aligned with the wafer chuck. The wafer is supported at its underside. At block 1706, the end effector is lowered to place the wafer on the wafer risers. The end effector is lowered away from the wafer at block 1708 and is withdrawn at block 1710. At block 1712, the wafer risers are lowered to place the wafer on the wafer chuck and a vacuum is applied to hold the wafer on the wafer chuck. In this manner, the same wafer chuck may be used to hold wafers with die and wafers without die. In turn, this saves time that would otherwise be used in changing wafer chucks.

A wafer chuck assembly may include both holder risers, which may be actuated for raising and lowering the object holders above a water level in a scan tank, and wafer risers for supporting a wafer above a wafer chuck to allow the underside of a wafer to be touched when handling.

In this document, relational terms such as first and second, top and bottom, and the like may be used solely to distinguish one entity or action from another entity or action without necessarily requiring or implying any actual such relationship or order between such entities or actions. The terms “comprises,” “comprising,” “includes,” “including,” “has,” “having,” or any other variations thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

Reference throughout this document to “one embodiment,” “certain embodiments,” “an embodiment,” “implementation(s),” “aspect(s),” or similar terms means that a particular feature, structure, or characteristic described in connection with the embodiment is included in at least one embodiment of the present disclosure. Thus, the appearances of such phrases or in various places throughout this specification are not necessarily all referring to the same embodiment. Furthermore, the particular features, structures, or characteristics may be combined in any suitable manner in one or more embodiments without limitation.

The term “or,” as used herein, is to be interpreted as an inclusive or meaning any one or any combination. Therefore, “A, B or C” means “any of the following: A; B; C; A and B; A and C; B and C; A, B and C.” An exception to this definition will occur only when a combination of elements, functions, steps or acts are in some way inherently mutually exclusive.

As used herein, the term “configured to,” when applied to an element, means that the element may be designed or constructed to perform a designated function, or that is has the required structure to enable it to be reconfigured or adapted to perform that function.

Numerous details have been set forth to provide an understanding of the embodiments described herein. The embodiments may be practiced without these details. In other instances, well-known methods, procedures, and components have not been described in detail to avoid obscuring the embodiments described. The disclosure is not to be considered as limited to the scope of the embodiments described herein.

Those skilled in the art will recognize that the present disclosure has been described by means of examples. The present disclosure could be implemented using hardware component equivalents such as special purpose hardware and/or dedicated processors which are equivalents to the present disclosure as described and claimed. Similarly, dedicated processors and/or dedicated hard wired logic may be used to construct alternative equivalent embodiments of the present disclosure.

Various embodiments described herein are implemented using dedicated hardware, configurable hardware or programmed processors executing programming instructions that are broadly described in flow chart form that can be stored on any suitable electronic storage medium or transmitted over any suitable electronic communication medium. A combination of these elements may be used. Those skilled in the art will appreciate that the processes and mechanisms described above can be implemented in any number of variations without departing from the present disclosure. For example, the order of certain operations carried out can often be varied, additional operations can be added, or operations can be deleted, without departing from the present disclosure. Such variations are contemplated and considered equivalent.

The various representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

What is claimed is:

1. An ultrasonic inspection system comprising:
one or more ultrasonic scanning stations;
one or more support structures each moveable between a first orientation and a second orientation;
a plurality of object holders coupled to a support structure of the one or more support structures and including at least first and second object holders, each object holder configured to hold an object for ultrasonic scanning, where:
in the first orientation of the support structure, a first object holder is positioned to allow loading or unloading of the first object holder and a second object holder is positioned in an ultrasonic scanning station of the one or more ultrasonic scanning stations; and
in the second orientation of the support structure, the second object holder is positioned to allow loading or unloading of the second object holder and the first object holder is positioned in the ultrasonic scanning station of the one or more ultrasonic scanning stations.

2. The ultrasonic inspection system of claim 1, where at least one of the plurality of object holders is a wafer chuck configured to hold a semiconductor wafer for ultrasonic scanning.

3. The ultrasonic inspection system of claim 1, where the support structure of the one or more support structures is coupled to a plurality of object holders.

4. The ultrasonic inspection system of claim 1, where the one or more ultrasonic scanning stations comprises two ultrasonic scanning stations, and the one or more support structures comprises two support structures.

5. The ultrasonic inspection system of claim 1, where an ultrasonic scanning station of the one or more ultrasonic scanning stations includes an ultrasonic transducer and a water coupler.

6. The ultrasonic inspection system of claim 1, further including a scan tank, where an object holder positioned in an ultrasonic scanning station is configured to hold an object in the scan tank.

7. The ultrasonic inspection system of claim 6, where an object holder is coupled to the support structure by one or more holder risers configured to move the object holder between a first position above a water level of the scan tank for loading and unloading, and a second position below the water level of the water in the scan tank for ultrasonic scanning.

8. The ultrasonic inspection system of claim 6, where an object holder is coupled to the support structure by two or more holder risers configured to adjust a tilt of the object holder in an ultrasonic scanning station of the one or more scanning stations.

9. The ultrasonic inspection system of claim 1, where an object holder of the plurality of object holders is a wafer chuck, the ultrasonic inspection system further including a plurality of wafer risers located in a peripheral region of the wafer chuck and configured to:
support a semiconductor wafer in a first position above the wafer chuck that enables a robotic positioning arm to pass between the wafer chuck and an underside of the semiconductor wafer; and
move to a second position, below the first position, to enable the semiconductor wafer to be supported, at its underside, by the wafer chuck.

10. The ultrasonic inspection system of claim 9, where wafer chuck has a complete outer ring configured to support an outer region of a wafer.

11. The ultrasonic inspection system of claim 1, where the support structure includes a rotatable index table.

12. A method of ultrasonic scanning comprising, for a plurality of objects to be scanned in an ultrasonic inspection system:
moving a support structure to a first orientation for which a first object holder coupled to the support structure is located outside of an ultrasonic scanning station of the ultrasonic inspection system and a second object holder coupled to the support structure is located in the ultrasonic scanning station;
performing an ultrasonic scan of an object in the second object holder;
unloading an object previously scanned from the first object holder;
loading an object of the plurality of objects to be scanned onto the first object holder;
moving the support structure to a second orientation for which the first object holder is located in the ultrasonic scanning station and the second object holder is located outside of the ultrasonic scanning station;
performing an ultrasonic scan of the object in the first object holder;
unloading an object, previously scanned, from the second object holder; and
loading an object to be scanned onto the second object holder.

13. The method of claim 12, where the moving includes rotation and where the support structure is a first support structure of an ultrasonic inspection system having a first support structure and a second support structure and two ultrasonic scanning stations, the method further comprising:
rotating the first support structure before rotation of the second support structure to provide sufficient clearance between the first and second support structures during rotation.

14. The method of claim 12, where the support structure is a first support structure of an ultrasonic inspection system having a first support structure and a second support structure and two ultrasonic scanning stations, the method further comprising:
moving a second support structure to a first orientation for which a third object holder coupled to the second support structure is located outside of an ultrasonic scanning station of the ultrasonic inspection system and a fourth object holder coupled to the second support structure is located in the ultrasonic scanning station;
performing an ultrasonic scan of an object in the fourth object holder;
unloading an object previously scanned from the third object holder;
loading an object of the plurality of objects to be scanned onto the third object holder;
moving the second support structure to a second orientation for which the third object holder is located in the ultrasonic scanning station and the fourth object holder is located outside of the ultrasonic scanning station;
performing an ultrasonic scan of the object in the third object holder;
unloading an object, previously scanned, from the fourth object holder; and
loading an object to be scanned onto the fourth object holder.

15. The method of claim 12, further comprising:
raising the first object holder out of a water tank for unloading an object previously scanned from the first object holder;
lowering the first object holder into the water tank for scanning an object in the first object holder;
raising the second object holder out of a water tank for unloading an object previously scanned from the second object holder; and
lowering the second object holder into the water tank for scanning an object in the second object holder.

16. The method of claim 12, where raising or lowering the first object holder includes actuating one or more holder risers that couple between the first object holder and the support structure.

17. The method of claim 12, where raising or lowering the first object holder includes actuating a plurality of holder risers that couple between the first object holder and the support structure and located in a peripheral region of the first object holder.

18. The method of claim 17, further comprising: adjusting an orientation of the first object holder using the plurality of holder risers.

19. The method of claim 12, where the first object holder is a wafer chuck, the method further comprising:
raising a plurality of wafer risers located in a peripheral region of the wafer chuck;
placing a semiconductor wafer on the plurality of wafer risers using a robotic positioning arm positioned between a lower surface of the semiconductor wafer and an upper surface of the wafer chuck;
withdrawing the robotic positioning arm; and
lowering the plurality of wafer risers to place an underside of semiconductor wafer on the upper surface of the wafer chuck.

20. The method of claim 12, where:
in the first orientation, a third object holder coupled to the support structure is located outside of a second ultrasonic scanning station of the ultrasonic inspection system and a fourth object holder coupled to the support structure is located in the second ultrasonic scanning station; and
in the second orientation, the third object holder is located in the second ultrasonic scanning station and the fourth object holder is located outside of the second ultrasonic scanning station.
